(19) United States
(12) Patent Application Publication
(10) Pub. No.: US 2005/0079729 A1
(43) Pub. Date: Apr. 14, 2005

(54) High density plasma oxide film deposition apparatus having a guide ring and a semiconductor device manufacturing method using the same

(76) Inventor: Woo-Sung Jang, Anyang-City (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/680,188

(22) Filed: Oct. 8, 2003

(51) Int. Cl. H01L 21/31

(52) U.S. Cl. 438/758

(57) ABSTRACT

A high density plasma (HDP) oxide film deposition apparatus and method of forming an HDP oxide film in a trench of a semiconductor substrate prevent an underlying nitride film, serving as a liner of the trench, from being torn during the plasma deposition process. A guide ring protects the semiconductor substrate within the processing chamber of the apparatus. The distance between the guide ring and the substrate is smaller than the free mean path of ions of the plasma when tuned to the frequency of the power applied to the apparatus. The power applied is also selected to minimize the momentum that the ions of the plasma can attain in a region between the substrate and the guide ring. In addition, the nitride film is formed to a thickness of only 25-40 Å before the HDP oxide film deposition process is carried out, so that ions of the plasma can be adsorbed by the semiconductor substrate without reacting with the nitride film.

### BACKGROUND OF THE INVENTION

1. Field of the Invention

The present invention generally relates to an apparatus for and a method of manufacturing a semiconductor device. More specifically, the present invention relates to a high density plasma oxide film deposition apparatus having a guide ring and to a semiconductor device manufacturing method using the same.

2. Description of the Related Art

Semiconductor device manufacturing often employs a technique, such as a trench isolation process, to attain a high degree of integration for the semiconductor device. Key aspects of the trench isolation process include: the forming of a narrow and deep trench region by etching a predetermined region of a semiconductor substrate, and the filling of the trench with an insulating film having excellent step coverage.

Recently, a HDP (High Density Plasma) oxide film is being widely used as an insulating film for filling recessed regions like trenches. The HDP oxide film is formed by repeatedly carrying out a deposition process and an etching process one after the other. The HDP oxide film is an excellent insulator between semiconductor devices because it can be formed in a trench without incurring a void.

A conventional HDP oxide film deposition apparatus includes a chamber, an electrostatic chuck installed in the chamber, a guide ring surrounding the electrostatic chuck, and an upper electrode spaced a predetermined distance above an upper surface of the electrostatic chuck.

A semiconductor substrate is loaded on the electrostatic chuck. Subsequently, power having a radio frequency of 13.5 MHz is applied to the electrostatic chuck, and power having a radio frequency of 2 MHz is applied to the upper electrode. Process gas, such as silane (SiH₄) and oxygen (O₂), are injected into the chamber. The process gas is transformed into plasma by the power supplied to the upper electrode. An oxide film is formed on the semiconductor substrate in the chamber by the plasma.

An example of the above-described HDP oxide film deposition apparatus and method has been disclosed in U.S. Pat. No. 6,284,093, entitled “SHIELD OR RING SURROUNDING SEMICONDUCTOR WORKPIECE IN PLASMA CHAMBER”. The semiconductor manufacturing apparatus disclosed in U.S. Pat. No. 6,284,093 comprises an electrostatic chuck which supports the semiconductor substrate, a cathode electrode, a guide ring, and a protective ring disposed in a processing chamber. The electrostatic chuck is disposed on the cathode electrode in a lower part of the chamber. The guide ring surrounds and contacts a lower portion of the cathode electrode. A protective ring extends around an upper portion of the cathode electrode. The guide ring is in contact with the protective ring.

The cathode electrode serves to direct the plasma onto the semiconductor substrate when the RF power is applied. The guide ring protects the semiconductor substrate, whereas the protective ring prevents plasma ions from attacking the upper portion of the guide ring. The guide ring and the protective ring are spaced radially from the semiconductor substrate by predetermined amounts. Thus, the plasma ions are directed onto not only the semiconductor substrate but also into the space between the substrate and the protective and guide rings. A plasma discharge is inevitably created in the space when electric charges different from those at the cathode electrode are induced onto the guide ring and the protective ring due to a capacitive effect under the action of the power applied to the cathode electrode.

A guide ring of another prior art high density plasma oxide film deposition apparatus will next be described with reference to FIGS. 1A-1C.

The guide ring (5) of prior art high density plasma oxide film deposition apparatus include a first annular portion (12) and a second annular portion (10) protruding upwardly from the outer periphery of the first annular portion (12). The first annular portion (12) has a first inside diameter (16) and a first outside diameter (20), and the second annular portion (10) has a second inside diameter (18) and a second outside diameter (20) that is the same as the first outside diameter (20) of the first annular portion (12). The second inside diameter (18) is greater than the first inside diameter (16). Thus, the guide ring (5) has an inner intermediate wall extending vertically from the first annular portion (12) and which wall establishes the second inside diameter (18).

An electrostatic chuck (14) is disposed radially inwardly of and spaced from the first annular portion (12) of the guide ring (5). The upper surface of the electrostatic chuck (14) is situated just a little above the upper surface of the first annular portion (12) of the guide ring (5).

Referring to FIG. 1C, an upper electrode (22) is disposed above the electrostatic chuck (14). The electrostatic chuck (14), the guide ring (5), and the upper electrode (22) are mounted in a sealed chamber (28). The upper electrode (22) is connected to a first power source (V1), and the electrostatic chuck (14) is connected to a second power source (V2). The first power source (V1) has a bias power and a radio frequency within a range of 2000˜3000 Watts and 1.8˜2.2 MHz, respectively. The second power source (V2) has a bias power and a radio frequency within a range of 2000˜3000 Watts and 13.37˜13.64 MHz, respectively.

Accordingly, plasma (24) is formed between the upper electrode (22) and the semiconductor substrate (26) when process gases, such as silane (SiH₄) and oxygen, are supplied into the chamber (28) and the first and the second power sources (V1, V2) provide power to the upper electrode (22) and the electrostatic chuck (14). Consequently, a material film, such as an oxide film, is formed on an upper surface of the semiconductor substrate (26).

The inside diameter (18) of the second annular portion (10) of the guide ring (5) is larger than the diameter of a semiconductor substrate (26) so that the semiconductor substrate can be safely mounted on the electrostatic chuck (14). Accordingly, a predetermined interval (W1) is left between the semiconductor substrate (26) and the second annular portion (10). The second annular portion (10) nonetheless prevents the semiconductor substrate from being separated from the electrostatic chuck (14).

FIG. 1D shows a section of semiconductor substrate before an HDP oxide film is formed thereon using the prior art high density plasma oxide film deposition apparatus.

As shown in FIG. 1D, an active nitride film (46) and an insulating film (48) are sequentially formed at an upper part (40) of the semiconductor substrate (26) but not at a lower part (44) of the semiconductor substrate (26) before the HDP oxide deposition process takes place. In addition, a nitride film liner (50) is formed over the entire upper surface of the semiconductor substrate (26), including over the active nitride film (46) and the insulating film (48). For the sake of simplicity, the drawing omits a pad oxide film that is formed over the entire upper surface of the semiconductor substrate (26), and a trench formed in the substrate (26) as dividing an active region from inactive region of the substrate (26) through the active nitride film (46).

The predetermined interval (W1) between the beveled part of the semiconductor substrate (26) and the upper annular portion (10) of the guide ring (5) is typically 1.75 mm. Accordingly, plasma ions migrate toward the semiconductor substrate (26) within a parasitic discharge region, namely, a region corresponding to the predetermined interval (W1), in addition to the upper surface of the semiconductor substrate (26), when the HDP oxide film deposition is performed. The plasma ions attack a beveled part (A1) of the side of the semiconductor substrate (26) at the parasitic discharge region. In particular, the attack is especially severe at a lower region (52) of the beveled part (A1).

FIG. 1E is a photo of the beveled part (A1) after the HDP oxide film has been formed on the semiconductor substrate (26). As shown in FIG. 1E, the region (52) of the beveled part (A1) has been attacked by oxygen (O) ions of the plasma. Check points (54, 56) of the photo show local regions whose color differs from those of the surrounding regions. This indicates that the nitride film (50) has swelled up by reacting with the oxygen (O) ions, or that the nitride film (50) has been locally torn out.

The severity of the attack shown in FIG. 1E stems from the fact that the oxygen ions are tuned to the radio frequency of the second power source (V2) during the deposition process. At this time, the mean free path of the oxygen ions is greater than the width of the parasitic discharge region, namely the predetermined interval (W1) between the guide ring and the substrate as shown in FIG. 1C. Accordingly, the oxygen ions tuned to the frequency of the second power source (V2) collide with the beveled part (A1) in the parasitic discharge region with the greatest amount of momentum.

The torn nitride film forms a break in a contact connecting semiconductor devices. Also, a loose of the torn nitride film can become lodged on an upper part of the semiconductor substrate during the HDP oxide deposition process, thereby causing a bridge between semiconductor device patterns.

FIG. 2A shows a semiconductor substrate having a nitride film used as a liner of a trench according to prior art, before an HDP oxide layer is formed thereon. An active nitride film (62) and an insulating film (60) are sequentially formed on the substrate (66) over a portion of the beveled part of the semiconductor substrate (66) and over an upper surface (64) of the substrate (66), but not a lower surface (72) of the semiconductor substrate (66). In addition, the entire surface of the semiconductor substrate (66) is covered with a nitride film (70), including over the active nitride film (62) and the insulating film (60). The semiconductor substrate is processed in essentially the same as that shown in FIG. 1D. However, in this case, the nitride film (70) is formed to a selective thickness (T1) of 45, 50, 55 Å.

FIGS. 2B through 2D are photos showing beveled parts of semiconductor substrates (66) of FIG. 2A after a high density plasma oxide film has been formed thereon using the HDP oxide film deposition apparatus of FIG. 2C. The photos reveal the degree to which predetermined regions (68) of the beveled parts of the semiconductor substrates (66) have been attacked by plasma ions. More specifically, FIG. 2B shows a case in which a nitride film (70) has been formed on a semiconductor substrate (66) to a thickness (T1) of 45 Å; FIG. 2C shows a case in which a nitride film (70) has been formed on a semiconductor substrate (66) to a thickness (T1) of 50 Å. FIG. 2D shows a case in which the nitride film (70) has been deposited on the semiconductor substrate (66) to a thickness of 55 Å.

The table mentioned below shows correlations between the thickness (T1) of the nitride film (70) deposited on the semiconductor substrate (66) and the existence of tears in the nitride film (70) after the HDP oxide deposition process.

TABLE 1

| Thickness of nitride | HDP oxide deposition | Presence of tears in |
|---|---|---|
| film (Å) | conditions | nitride film |
| 45 | Using the HDP oxide film | Yes |
| 50 | deposition apparatus of | Yes |
| 55 | FIG. 1C having the guide | Yes |
| | ring (5) and power | |
| | sources (V1, V2) | |

As the results tabulated above show, a nitride film formed according to the prior art to any of the conventional thicknesses for use as a liner is subject to an attack of plasma ions created in the parasitic discharge region shown in FIG. 1C. Thus, according to the prior art, the HDP oxide film deposition process is always accompanied by an attack on the underlying nitride film (liner layer) at the beveled part of the semiconductor substrate. Such attacks lower the yield of the semiconductor devices.

### SUMMARY OF THE INVENTION

It is therefore an object of the present invention to provide a high density plasma oxide deposition apparatus having a guide ring capable of mitigating an attack on a beveled part of a semiconductor substrate.

It is another object of the present invention to provide a method of manufacturing a semiconductor device using a high density plasma deposition apparatus having a guide ring, wherein the power applied to an electrostatic chuck surrounded by the guide ring and an upper electrode is capable of preventing an attack on a beveled part of a semiconductor substrate.

It is still another object of the present invention to provide a method of manufacturing a semiconductor device, which includes using a high density plasma deposition apparatus having a guide ring, and wherein a nitride film that serves as a liner on the semiconductor substrate is formed to a thickness that prevents it from being subsequently attacked during the HDP oxide film deposition process.

According to one aspect of the present invention, a high density plasma oxide deposition apparatus comprises a chuck, such as an electrostatic chuck, an upper electrode confronting and spaced from the upper surface of said chuck, and a guide ring having a first annular portion, a second annular portion disposed over the first annular portion and preferably concentric therewith, and at least three protrusions extending radially inwardly from the second annular portion.

The first annular portion has an inner peripheral side wall surrounding the outer peripheral side wall of the chuck. The second annular portion extends upwardly from an outer peripheral region of the first annular portion and has an inner peripheral side wall disposed radially outwardly of the inner peripheral side wall of the first annular portion. The protrusions extend from the inner peripheral side wall of the second annular portion toward the inner peripheral side wall of the first annular portion, and are spaced from one another (preferably, equidistantly) in the circumferential direction of the second annular portion. The protrusions have terminal ends remote from the inner peripheral side wall of the second annular portion and situated radially outwardly of the inner peripheral side wall of the first annular portion. Accordingly, the terminal ends of the protrusions lie along a circle whose diameter is greater than the inner diameter of said first annular portion of the guide ring.

According to another aspect of the present invention, a high density plasma oxide deposition apparatus comprises a chuck, such as an electrostatic chuck, an upper electrode confronting and spaced from the upper surface of said chuck, and a guide ring having a first annular portion, a second annular portion disposed over the first annular portion and preferably concentric therewith, and a third annular portion protruding upwardly from an upper surface of the second annular portion of the guide ring for guiding a semiconductor substrate onto the chuck.

The third annular portion of the guide ring has an inclined inner peripheral side wall extending contiguously from the inner peripheral side wall of the second annular portion such that the inside diameter of the third annular portion at the top of the inclined wall is greater than the inside diameter of the third annular portion at the bottom of the inclined wall. The third annular portion also has openings through which respective parts of the upper surface of the second annular portion are exposed.

In this case, the difference between the inside diameter of the second annular portion and the diameter of the semiconductor substrate is preferably less than 0.25 mm.

Also, in either of the apparatuses described above, a first power source having a bias and a radio frequency within ranges of 2000˜3000 Watts and 1.8˜2.2 MHz, respectively, is connected to the upper electrode. A second power source having a bias and a radio frequency within ranges of 2000˜3000 Watts and 13.37˜13.64 MHz, respectively, is preferably connected to a lower electrode, such as the chuck itself. Alternatively, the first power source may have a bias and a radio frequency within ranges of 2000˜3000 Watts and 13.37˜13.64 MHz, respectively, in which case the second power source has a bias and a radio frequency within ranges of 2000˜3000 Watts and 1.8˜2.2 MHz, respectively.

According to yet another aspect of the present invention, a method of manufacturing a semiconductor device, including using a high density plasma oxide deposition apparatus having a guide ring, comprising providing a semiconductor substrate having a nitride film on the substrate as a liner, injecting process gases, including oxygen, into the chamber of the apparatus, and subsequently applying a first power having a bias and a radio frequency within ranges of 2000˜3000 Watts and 13.37˜13.64 MHz, respectively, to an upper electrode of the apparatus to convert the process gases into plasma, and applying a second power having a bias and a radio frequency within ranges of 2000˜3000 Watts and 1.8˜2.2 MHz, respectively, to a lower electrode situated beneath the semiconductor substrate and the guide ring to attract ions of the plasma onto the semiconductor substrate, whereby an HDP oxide film is formed.

In addition, before the HDP oxide film deposition process, a pad oxide film and an active nitride film are sequentially formed on the semiconductor substrate such that the active nitride film divides an active region from an inactive region of the substrate. The pad oxide film and the semiconductor substrate are, sequentially etched in the inactive region using the active nitride film as a mask to thereby form a trench in the substrate. Next, an insulating film is formed on the active nitride film and in the trench. The active nitride film is then removed from the beveled part of the semiconductor substrate and from the lower surface of the semiconductor substrate using the insulating film as a mask.

Then the nitride film serving as a liner for the semiconductor substrate is formed on the insulating film.

According to another aspect of the present invention, when the semiconductor substrate is pre-processed this way, the nitride film serving as a liner for the semiconductor substrate is formed on the insulating film to a predetermined thickness within a range of 25˜40 Å.

In this case, the subsequent HDP oxide film deposition process is preformed by applying a first power having a bias and a radio frequency within ranges of 2000˜3000 Watts and 1.8˜2.2 MHz, respectively, to the upper electrode, and by applying a second power having a bias and a radio frequency within ranges of 2000˜3000 Watt and 13.37˜13.64 MHz, respectively, to the lower electrode (e.g., the chuck). Alternatively, the first power may have a bias and a radio frequency within ranges of 2000˜3000 Watts and 13.37˜13.64 MHz, respectively, in which case the second power has a bias and a radio frequency within ranges of 2000˜3000 Watts and 1.8˜2.2 MHz, respectively.

### BRIEF DESCRIPTION OF THE DRAWINGS

The above and other objects and advantages of the present invention will become readily apparent from the description that follows, with reference to the accompanying drawings, in which:

FIG. 1A is a plane view of a guide ring and an electrostatic chuck of an HDP (High Density Plasma) oxide film deposition apparatus according to the prior art;

FIG. 1B is a perspective view of a portion of the guide ring of FIG. 1a;

FIG. 1C is a sectional view of the HDP oxide film deposition apparatus according to the prior art, as taken in the direction of line I-I′ of FIG. 1A;

FIG. 1D is a sectional view of a semiconductor substrate before an HDP oxide film is formed thereon using the HDP oxide film deposition apparatus of the prior art;

FIG. 1E is a photo of a beveled part of the semiconductor substrate, shown in FIG. 1D, after the HDP oxide film has been formed thereon;

FIG. 2A is a sectional view of a semiconductor substrate having a nitride film that serves to line a trench according to the prior art;

FIG. 2B through FIG. 2D are photos of a beveled part of the semiconductor substrate of FIG. 2A after a high density plasma oxide film has been formed thereon;

FIG. 3A is a plan view of a first embodiment of a guide ring according to the present invention, as paired with an electrostatic chuck;

FIG. 3B is a perspective view of a portion (P2) of the guide ring of FIG. 3A;

FIG. 3C is a sectional view of an HDP oxide film deposition apparatus employing the guide ring of FIG. 3A according to the present invention, as taken in the direction of line II-II′ of FIG. 3A;

FIG. 3D is a photo of a beveled part of a semiconductor substrate on which an HDP oxide film was formed using the high density plasma oxide film deposition apparatus of FIG. 3C;

FIG. 4A is a plan view of a second embodiment of a guide ring according to the present invention, as paired with an electrostatic chuck;

FIG. 4B is a perspective view of a portion (P3) of the guide ring of FIG. 4A;

FIG. 4C is a sectional view of an embodiment of an HDP oxide film deposition apparatus employing the guide ring of FIG. 4A according to the present invention, as taken in the direction of line II-II′ of FIG. 4A;

FIG. 4D is a photo of a beveled part of a semiconductor substrate on which an HDP oxide film was formed using the high density plasma oxide film deposition apparatus of FIG. 4C;

FIG. 5A is a schematic diagram of a high density plasma oxide film deposition apparatus according to the present invention, showing the power sources and the components connected thereto within the processing chamber;

FIG. 5B is a photo of a beveled part of a semiconductor substrate on which an HDP oxide film was formed using the high density plasma oxide film deposition apparatus of FIG. 5A;

FIG. 6A is a sectional view of a portion of a semiconductor substrate provided with an active nitride film and an insulating film before an HDP oxide film is formed thereon using a high density plasma oxide film deposition apparatus according to the present invention;

FIG. 6B is a sectional view of a portion of a semiconductor substrate to be etched and having the active nitride film shown in FIG. 6A;

FIG. 6C is a sectional view of a portion of a semiconductor substrate having the nitride film shown in FIG. 6B; and

FIG. 6D is a photo of a beveled part of the semiconductor substrate of FIG. 6C after an HDP oxide film has been formed thereon according to the present invention.

### DETAILED DESCRIPTION OF THE PREFERRED EMBODIMENTS

The present invention will now be described more fully hereinafter with reference to the accompanying drawings, in which preferred embodiments of the invention are shown. In the drawings, the thickness of layers and regions are exaggerated for clarity. It will also be understood that when a layer of material is referred to as being “on” another layer or substrate, such a description includes the layer of material being disposed directly on the other layer or substrate as well as other layers being present therebetween.

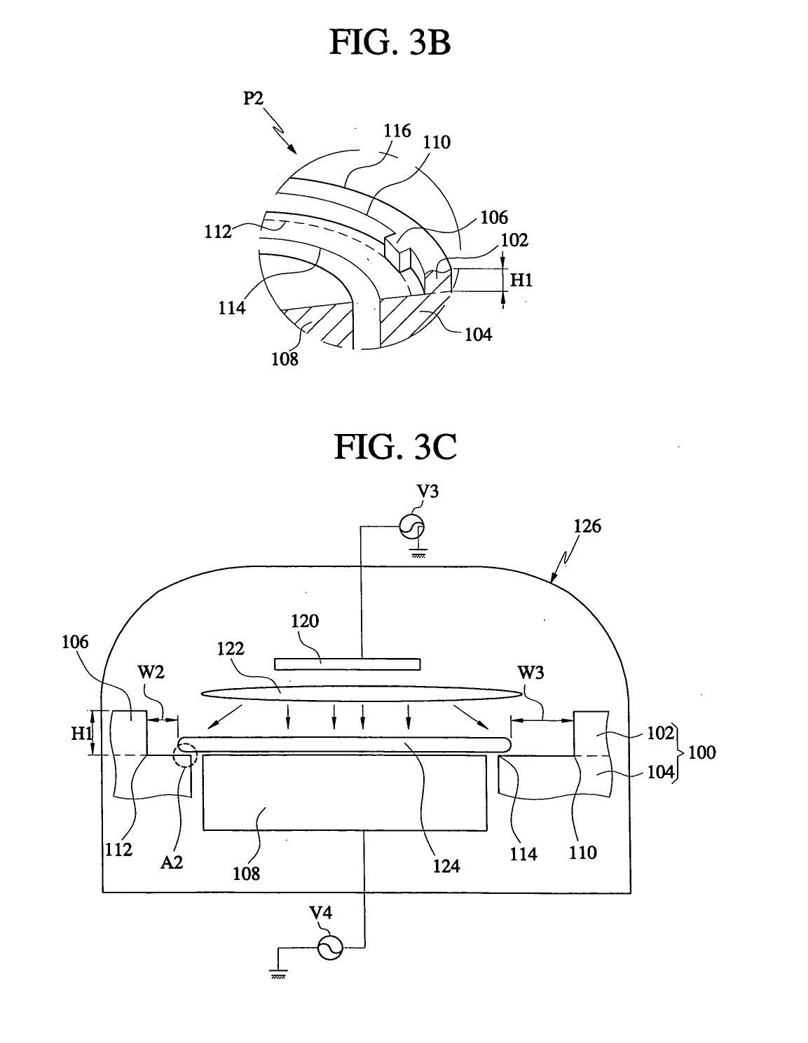

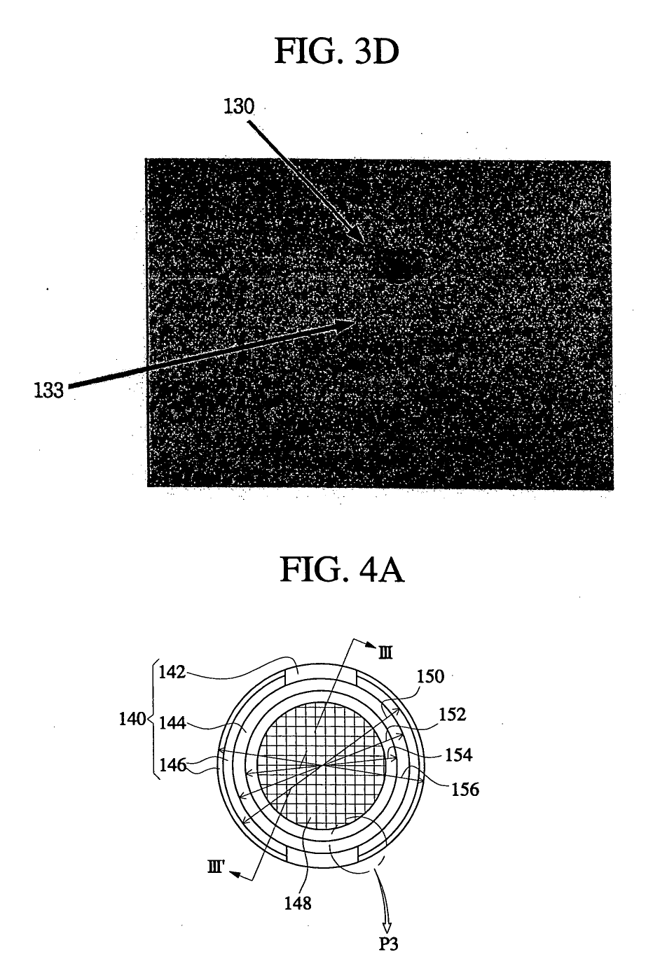

Referring first to FIGS. 3A-3C, the first embodiment of a guide ring (100) according to the present invention comprises a first annular portion (104) surrounding a side wall of an electrostatic chuck (108), and a second annular portion (102) disposed on the outer peripheral region of the first annular portion (104) and concentric with the first annular portion (104). The second annular portion (102) has an inside diameter (110) that is greater than the inside diameter (114) of the first annular portion (104), and an outside diameter (116) that is the same as the outside diameter (116) of the first annular portion (104).

Also, the second annular portion (102) has at least three protrusions (106) extending radially inwardly toward the inner peripheral vertical side wall of the first annular portion (104). The diameter (112) of a circle inscribing the protrusions (106) is greater than that of the inside diameter (114) of the first annular portion (102). The protrusions (106) are provided at regular intervals along the inner circumference of the second annular portion (102), whereby the angles subtended between lines connecting the protrusions (106) and the common center of the first (104) and second (102) annular portions are same.

FIG. 3C shows the HDP oxide film deposition apparatus in a state in which a semiconductor substrate (124) has been mounted to an electrostatic chuck (108) within processing chamber (126). The electrostatic chuck (108) is disposed radially inwardly of the guide ring (100) as spaced therefrom, and is situated a little higher than the first annular portion (104) of the guide ring (100), whereby the semiconductor substrate (124) can be easily set down on the electrostatic chuck (108) and pick up from the electrostatic chuck (108). An upper electrode (120) and an electrostatic chuck (108) are connected to first and second power sources (V3, V4), respectively. The first power source (V3) preferably has a bias and a radio frequency within ranges of 2000˜3000 Watts and 1.8˜2.2 MHz, respectively. The second power source (V4) preferably has a bias and a radio frequency within ranges of 2000˜3000 Watts and 13.37˜13.64 MHz, respectively. Alternatively, the first power source (V3) preferably has a bias and a radio frequency within ranges of 2000˜3000 Watts and 13.37˜13.64 MHz, respectively, and the second power source (V4) preferably has a bias and a radio frequency within ranges of 2000˜3000 Watts and 1.8˜2.2 MHz, respectively.

Also, as shown in FIG. 3C, the protrusions (106) establish two different intervals (W2, W3) diametrically between the semiconductor substrate (124) on the electrostatic chuck (108) and the guide ring (100), namely a first interval (W2) between the semiconductor substrate (124) and the circle (112) inscribing the protrusions (106) and a second interval (W3) between the semiconductor substrate (124) and the inner peripheral vertical side wall of the second annular portion (102). In a specific example of the present invention, the interval (W2) is 1.75 mm, whereas the interval (W3) is 6.75 mm.

Process gases, such as SiH₄ and 02, are injected into the chamber (126). The process gases are transformed into plasma (122) by sequentially providing the upper electrode (120) and the electrostatic chuck (108) with power from the first and second power sources (V3, V4), respectively. The plasma (122) is attracted to the semiconductor substrate (124) by the power applied to the electrostatic chuck (108), whereby an HDP oxide film is deposited on the semiconductor substrate (124). The silicon (Si) ions and oxygen (O) ions of the plasma (122) impinge on the semiconductor substrate (124). At this time, the upper surface of the first annular portion (104) of the guide ring (100) confronts and is spaced from the lower surface of the semiconductor substrate (124). The first and the second annular portions (104, 102) of the guide ring (100) form a step that confines the plasma (122). As a result, an HDP oxide film is formed on the substrate (124).

Also, the plasma ions (122) flow to the parasitic discharge regions corresponding to the intervals (W2, W3) between the guide ring (100) and the semiconductor substrate (124).

More specifically, the power provided by the second power source (V4) essentially electrically couples the electrostatic chuck (108) to the guide ring (100), such that capacitive electric charges are formed on the guide ring (100). Accordingly, the plasma (122) is induced to the parasitic discharge region. The capacitive electric charges prevent a discontinuity in the ions of the plasma (122) from occurring at the edge of the semiconductor substrate (124) and hence, prevent the process from being performed at different rates at the peripheral and central regions of the semiconductor substrate (124).

At this time, the oxygen ions of the plasma (122) supplied to the parasitic discharge regions bump into the beveled part (A2) of the semiconductor substrate (124). However, the mean free path of the oxygen ions is smaller than the predetermined interval (W3). Thus, the oxygen ions of the plasma are less likely to bump into the beveled part (A2) of the semiconductor substrate (124) with maximum momentum than compared to the prior art.

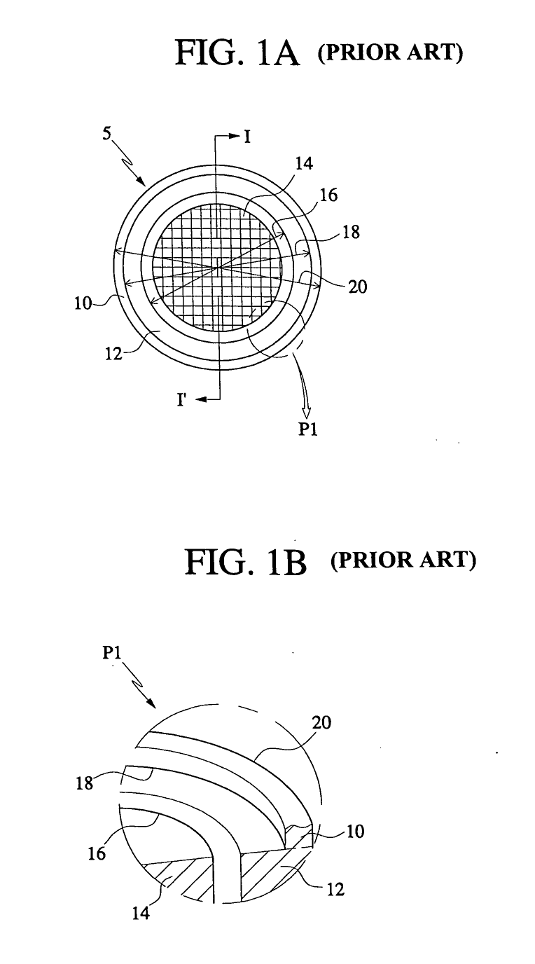

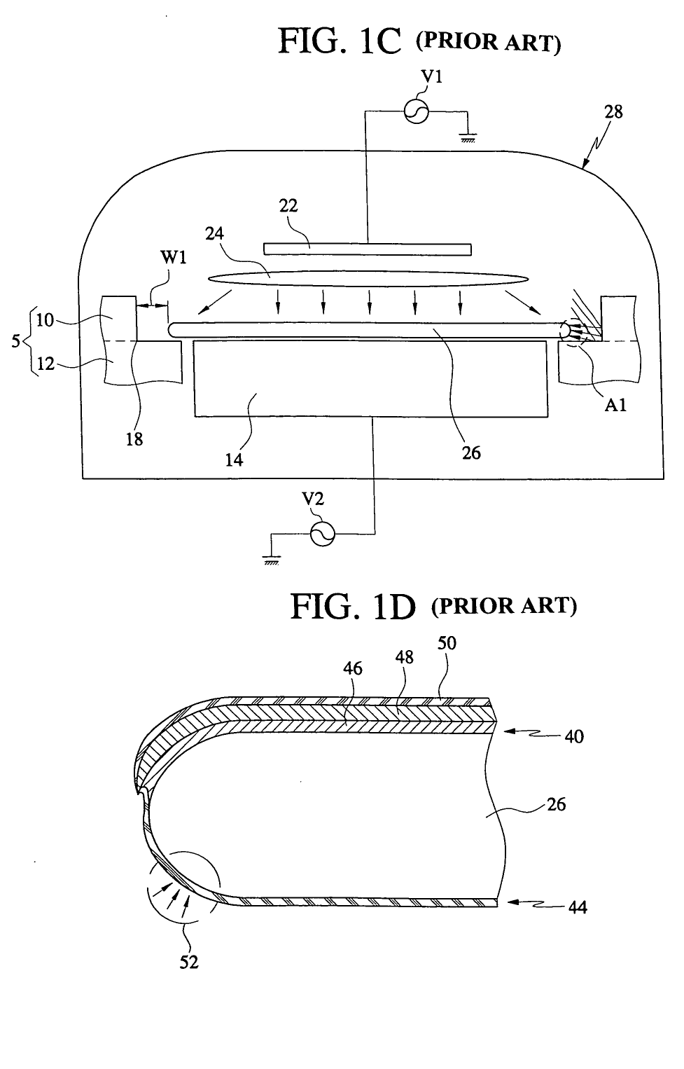

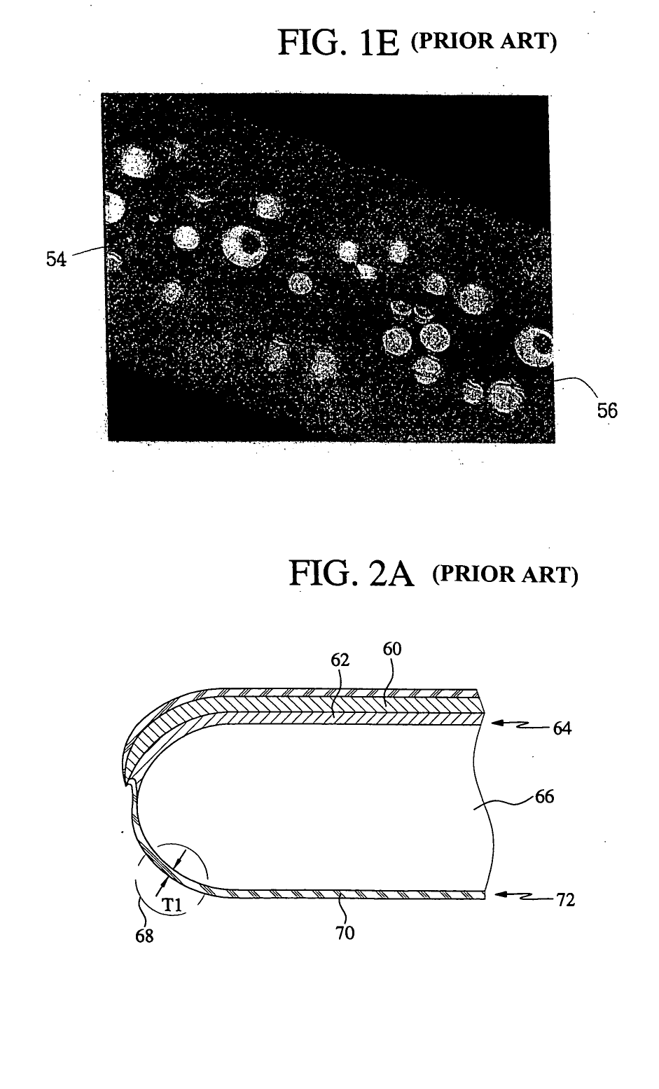

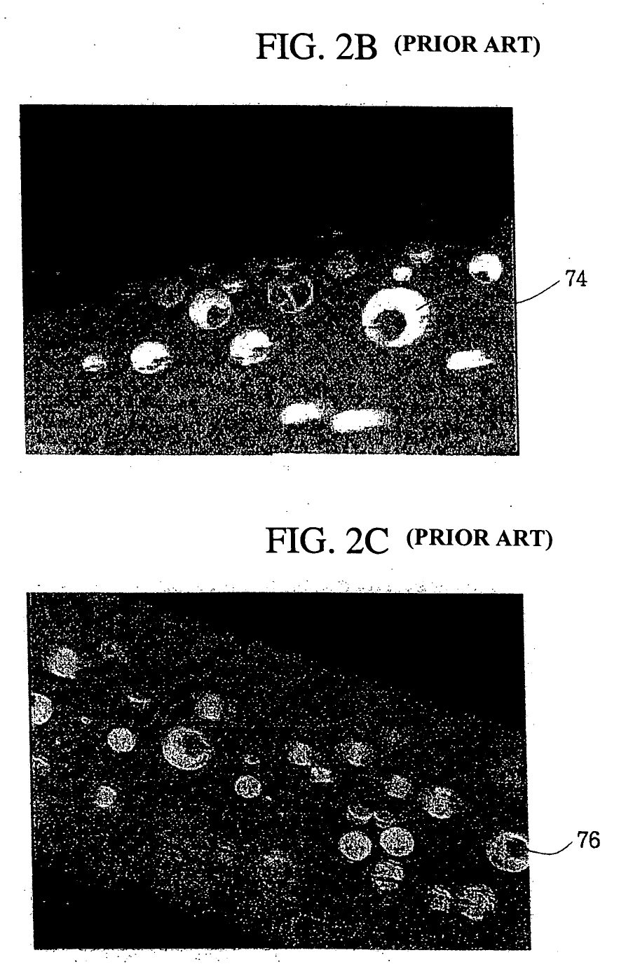

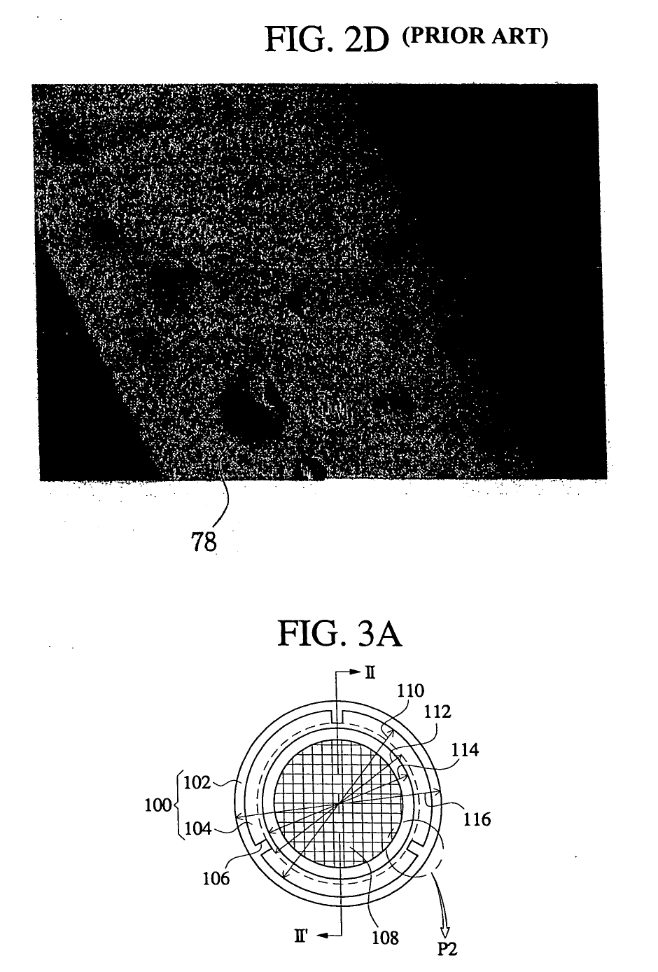

FIG. 3D shows a beveled part of a semiconductor substrate where a high density plasma oxide film has been formed using an HDP oxide film deposition apparatus having the guide ring of FIG. 3A. The state of the surface of the semiconductor substrate was the same as that of the semiconductor substrate (26) of FIG. 1D, before the HDP oxide film was formed thereon. However, the tearing of the nitride film (50) can be remarkably reduced by the HDP oxide film deposition apparatus according to the present invention, due to the provision of the different intervals (W2, W3) between the guide ring (100) and the semiconductor substrate (124). Nonetheless, the oxygen ions were still seen to form a hole and a scar in and on the nitride film at check points (130, 133). This phenomenon is attributed to the 1.75 mm interval (W2) still present between the semiconductor substrate (124) and the protrusions (106) of the guide ring (100).

After the deposition process, the second power source (V4) is turned off, and then the power from the first power source (V3) is interrupted. The injection of process gases into the chamber (126) is also stopped. Finally, the semiconductor substrate (124) is separated from the electrostatic chuck (108) and is transferred from the high density plasma oxide film deposition apparatus.

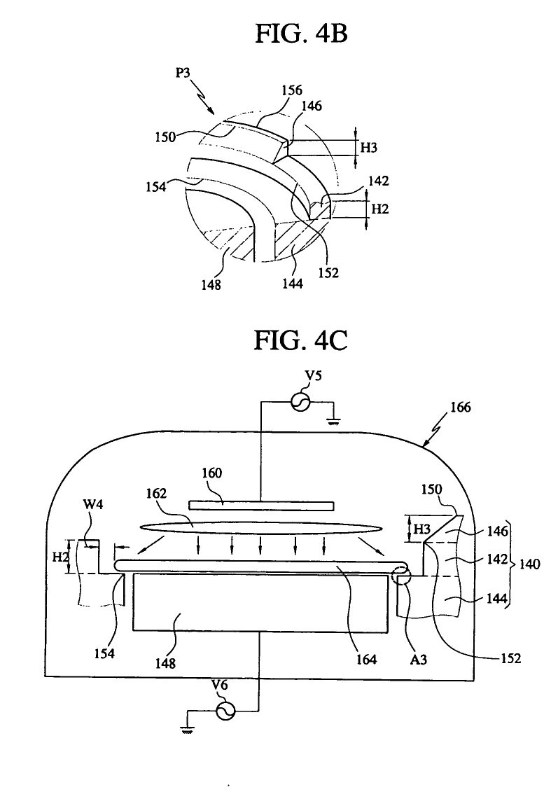

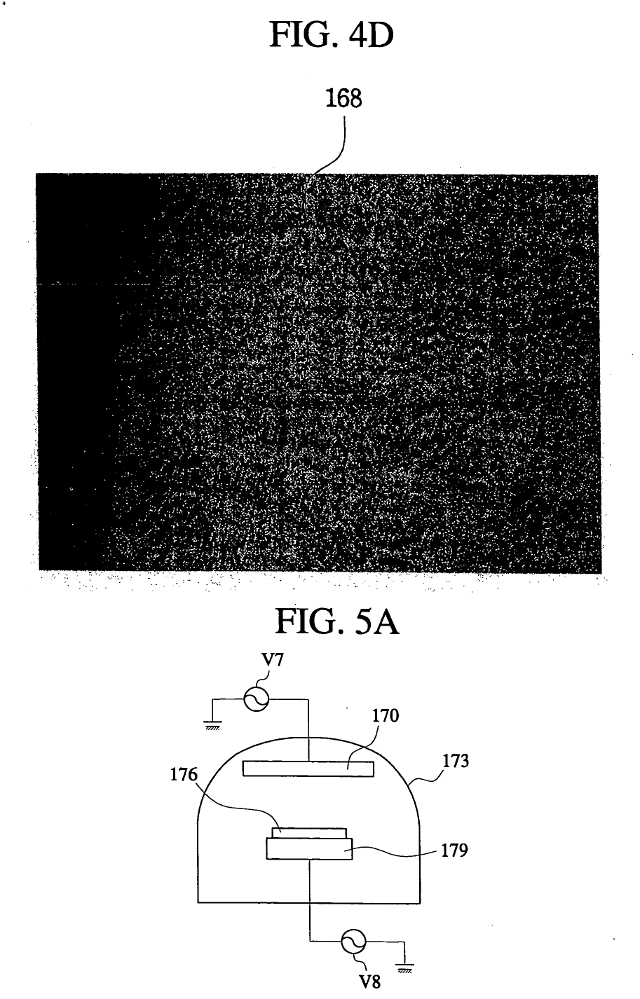

FIGS. 4A-4C show a second embodiment of the present invention. Referring first to FIGS. 4A and 4B, the guide ring (140) comprises a first annular portion (144) surrounding an electrostatic chuck (148), a second annular portion (142) extending upwardly a distance (H2, same as in the prior art) from an outer peripheral region of the first annular portion (144), and a third annular portion (146) extending upwardly a distance (H3) along part of the second annular portion (142). The first to the third annular portions (144, 142, 146) have the same outside diameter (156).

Moreover, the third annular portion (146) has a maximum width that is the same as the width of the second annular portion (142), and exposes parts of the upper surface of the second annular portion (142). The parts of the second annular portion (142) exposed by the third annular portion (146) correspond to regions into which a handler (not shown) fits when moving the semiconductor substrate (164) into and out of the guide ring (140). Also, the third annular portion (146) has an inclined inner peripheral side wall extending contiguously from a vertical inner peripheral side wall of the second annular portion (142). The third annular portion (146) better ensures that the semiconductor substrate (164) remains within the guide ring (140).

Accordingly, the third annular portion (146) of the guide ring (140) has an upper inner diameter (150) and a lower inner diameter (152), wherein the upper inner diameter (150) is greater than the lower inner diameter (152). Also, the lower inner diameter (152) is greater than the inner diameter (154) of the first annular portion (144).

FIG. 4C shows the HDP oxide film deposition apparatus in a state in which process gases, such as SiH₄ and O₂, injected into the chamber (166) a re changed into plasma (162) and directed onto the semiconductor substrate (164). To this end, power is sequentially supplied to an upper electrode (160) and an electrostatic chuck (148) from first and second power sources (V5, V6), respectively. Accordingly, the plasma ions (162) are attracted to the semiconductor substrate (164), whereby an HDP oxide film is deposited on the semiconductor substrate (164).

The first power source (V5) preferably has a bias and a radio frequency within ranges of 2000˜3000 Watts and 1.8˜2.2 MHz, respectively. The second power source (V6) has a bias and a radio frequency within ranges of 2000˜3000 Watts and 13.37˜13.64 MHz, respectively. Alternatively, the first power source (V5) has a bias a nd a radio frequency within ranges of 2000˜3000 Watts a nd 13.37˜13.64 MHz, respectively, and the second power source (V6) has a bias and a radio frequency within ranges of 2000˜3000 Watt and 1.8˜2.2 MHz, respectively.

During the deposition process, the lower surface of the semiconductor substrate (164) overlies but is separated from the upper surface of the first annular portion (144) of the guide ring (140). Also, the distance (W4), in the radial direction, between the inner peripheral side wall of the second annular portion (142) and the semiconductor substrate (164) is 0.25 mm.

In this embodiment, the ions of the plasma (160) can enter the parasitic discharge region, namely the region corresponding to interval (W4), between the guide ring (140) and the semiconductor substrate (124). There, the oxygen (O) ions impact a beveled part (A3) of the semiconductor substrate (164). However, it is very difficult for the oxygen ions to be tuned to the frequency (maximum frequency) of the second power source (V6) because the region corresponding to interval (W4) is very narrow, especially compared to the predetermined intervals in the prior art (W1) and in the first embodiment (W2, W3). In another words, the oxygen ions are absorbed into the semiconductor substrate (164) before attaining the maximum frequency, whereby an attack of the oxygen ions on the beveled part (A3) is minimized.

After the deposition process is performed, the flow of power to the electrostatic chuck (148) and the upper electrode (160) is interrupted in the foregoing sequence, the process gas is stopped from flowing into the chamber (166), and the semiconductor substrate (164) is separated from the electrostatic chuck (148). Finally, the semiconductor substrate (164) is removed from within the guide ring (140) and is transferred from the high density plasma oxide film deposition apparatus.

FIG. 4D shows a check point (168) of a beveled part of a semiconductor substrate where an HDP oxide film is deposited using a high density plasma oxide film deposition apparatus having the guide ring of FIG. 4A. In this case, namely before the HDP oxide film deposition process, the state of the surface of the semiconductor substrate was the same as that of the semiconductor substrate (26) shown in FIG. 1C. As is clear from the photo, the high density plasma oxide film deposition apparatus does not create a tear in the nitride film liner on the beveled part (A3) of the semiconductor substrate (164). That is, the photo of FIG. 4D confirms, according to the present invention, that oxygen ions are prevented from tearing the nitride film liner at the beveled part of a semiconductor substrate if the interval between the semiconductor substrate and the second annular portion of the guide ring is less than 0.25 mm.

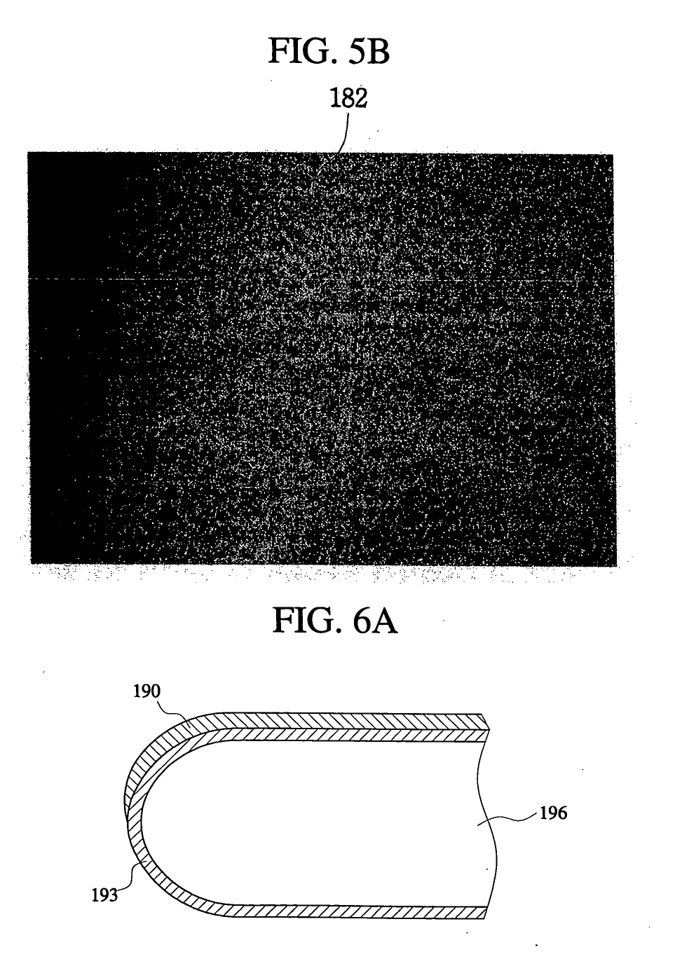

FIG. 5A shows a high density plasma oxide film deposition apparatus for performing an HDP plasma oxide deposition according to the present invention.

The high density plasma oxide film deposition apparatus includes a chamber (173), an electrostatic chuck (179) onto which a semiconductor substrate (176) is loaded, a guide ring (not shown but similar to that of the prior art shown in FIGS. 1A and 1B), and an upper electrode (170). In addition, a first power source (V7) is connected to the upper electrode (170). The first power source (V7) has a bias and a radio frequency within ranges of 2000˜3000 Watts and 13.37˜13.64 MHz, respectively. A second power source (V8) is connected to the electrostatic chuck (179). The second power source (V8) has a bias and a radio frequency within ranges of 2000˜3000 Watts and 1.8˜2.2 MHz, respectively.

The chamber (173) has basically the same set-up as the chamber (28) of the prior art shown in FIG. 1C. In particular, the interval between the guide ring (5) and the semiconductor substrate (176), i.e., the width of the parasitic discharge region, is 1.75 mm. However, the characteristics of the power supplied by the first and the second power sources (V7, V8) are reversed in comparison with the prior art shown in FIG. 1C.

That is, the second power source (V8) has frequency within a range of 1.8˜2.2 MHz rather than a frequency within a range of 13.37˜13.64 MHz. Accordingly, the oxygen ions obtain a relatively small maximum momentum in the parasitic discharge region, compared to the prior art of FIG. 1C.

Note, before the HDP oxide film deposition, the state of the surface of the semiconductor substrate (176) is the same as that of the semiconductor substrate (26) shown and described with reference to FIG. 1D. Specifically, the semiconductor substrate (176) is prepared by sequentially depositing a pad oxide film and an active nitride film thereon, the active nitride film dividing an active region from an inactive region of the substrate (176). Next, a trench (not shown) is formed by sequentially etching the pad oxide film located in the inactive region and the semiconductor substrate (176) using the active nitride film as a mask. An insulating film (not shown) is the formed on the active nitride film and in the trench. The active nitride film located on the beveled part of the semiconductor substrate (176) and on the lower surface of the semiconductor substrate (176) is etched away using the insulating film as a mask. Finally, the nitride film serving as a liner for the trench in the semiconductor substrate (176) is formed over the insulating film.

A method of forming an HDP oxide film using a high density plasma oxide film deposition apparatus employing the guide ring (5) of FIGS. 1A and 1B is as follows.

First, a semiconductor substrate (176) is mounted on the electrostatic chuck (179) within a guide ring identical to that of the guide ring (5) of FIGS. 1A-1C. Process gas composed of SiH₄ and 02 are injected into the chamber (173), and plasma is attracted to the semiconductor substrate (176) by sequentially applying a first RF power and a second RF power to upper electrode (170) and electrostatic chuck (179) from the power sources (V7, V8), respectively. Accordingly, the plasma ions form an HDP oxide film on the semiconductor substrate (176).

After the deposition process is completed, the power applied to the electrostatic chuck (179) and the upper electrode (170) in the chamber (173) is sequentially interrupted. The injecting of the process gas into the chamber (173) is stopped. Finally, the semiconductor substrate (176) is separated from the guide ring (5) and is taken out of the high density plasma oxide film deposition apparatus.

FIG. 5B is a photo showing a beveled part of a semiconductor substrate where an HDP oxide film has been formed using the HDP oxide film deposition apparatus of FIG. 5A according to the method described above.

As the check point (182) in the photo of FIG. 5B reveals, the nitride film at the beveled part of the semiconductor substrate shows no sign of being torn after the HDP oxide film deposition process has been performed. Also, this method can be applied to an HDP oxide film deposition apparatus having either the guide ring (100) of the embodiment of FIG. 3A or the guide ring (140) of the embodiment of FIG. 4A.

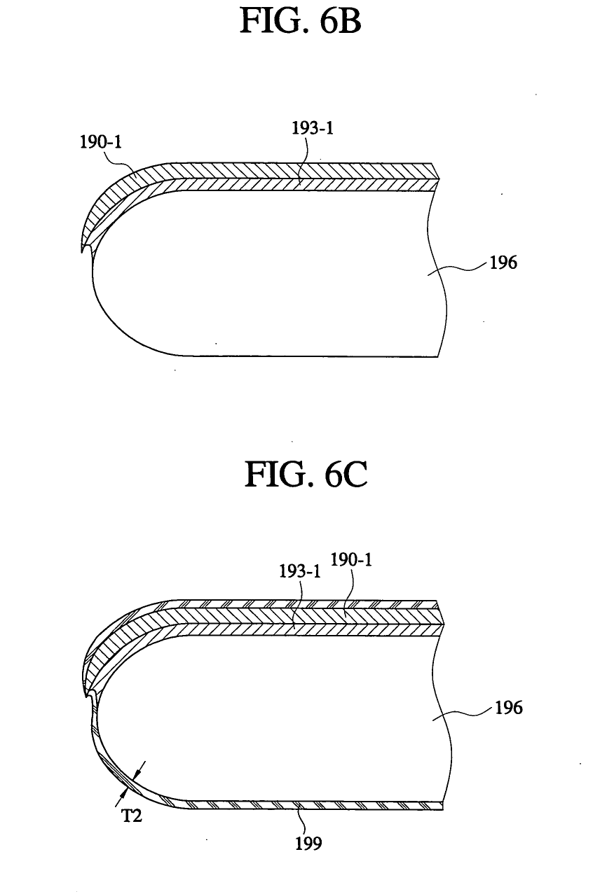

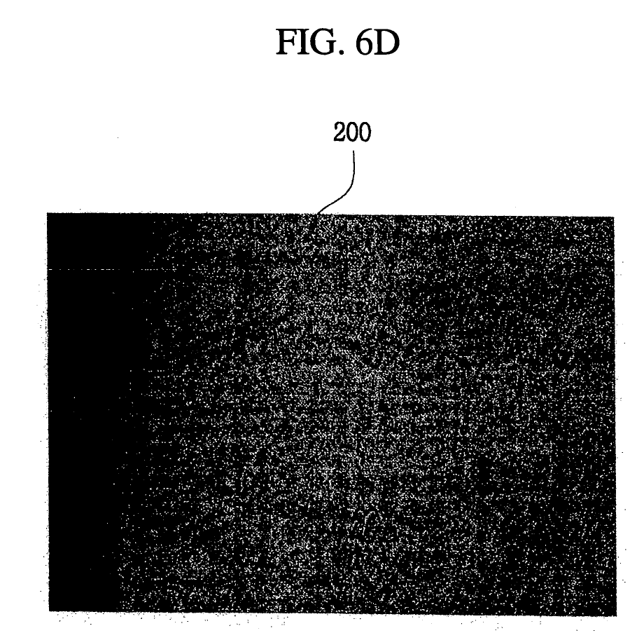

FIGS. 6A-6C illustrate another method of forming an HDP oxide film on a semiconductor substrate according to the present invention.

Referring first to FIG. 6A, the entire surface of a semiconductor substrate (196) is covered with an active nitride film (193). An upper surface and a portion of a beveled part of the semiconductor substrate (196) is then covered with an insulating film (190), including over active nitride film (193).

More specifically, a pad oxide film (not shown) and the active nitride film (193) are sequentially formed on the semiconductor substrate (196) such that the active nitride film (193) divides an active region of the substrate (196) from an inactive region (not shown). The active nitride film (193) is formed over the entire surface of the semiconductor substrate (196) using an LPCVD (Low Pressure Chemical Vapor Deposition) method. Next, a trench (not shown) is formed in the semiconductor substrate (196) by sequentially etching the pad oxide film located on the inactive region and the semiconductor substrate (196) using the active nitride film (193) as a mask. The insulating film (190) is then formed on the active nitride film (193) and in the trench, using a plasma deposition method. Next, the portion of the active nitride film (193) located on the beveled part and on the lower surface of the semiconductor substrate (190) is removed using the insulating film (190) as a mask.

As a result, the semiconductor substrate (196) is covered with an etched active nitride film (193-1) and an etched insulating film (190-1), as shown in FIG. 6B. The etching process is performed to prevent the semiconductor substrate (196) from deforming under the physical stress created between the active nitride film (193) and the semiconductor substrate (196) when the semiconductor substrate (196) is subsequently heated to harden the HDP oxide film.

Referring to FIG. 6C, a nitride film (199) is deposited on the semiconductor substrate (196) to a predetermined thickness (T2) within a range of 25-40 Å using an LPCVD method. The nitride film (199) thus lines the trench (not shown) in the semiconductor substrate (196). The predetermined thickness (T2) is preferably 30, 36, or 38 Å.

FIG. 6D, is a photo of a beveled part of a semiconductor substrate on which an HDP oxide film has been formed atop a nitride film (199) having a predetermined thickness (T2) within a range of 25-40 Å. The HDP oxide film deposition is performed using a high density plasma oxide deposition apparatus employing the guide ring (5) shown in the prior art of FIGS. 1A and 1B.

The power applied to the upper electrode of the high density plasma oxide film deposition apparatus has a bias and a radio frequency within ranges of 2000˜3000 Watts and 1.8˜2.2 MHz, respectively. The power applied to the electrostatic chuck has a bias and a radio frequency within ranges of 2000˜3000 Watts and 13.37˜13.64 MHz, respectively. Alternatively, the power applied to the upper electrode of the high density plasma oxide film deposition apparatus has a bias and a radio frequency within ranges of 2000˜3000 Watts and 13.37˜13.64 MHz, respectively, whereas the power applied to the electrostatic chuck has a bias and a radio frequency within ranges of 2000˜3000 Watts and 1.8˜2.2 MHz, respectively.

As is clear from the check point (200) of the photo of FIG. 6D, the nitride film (199) does not show any sign of tearing at the beveled part of the semiconductor substrate (196) after the HDP oxide deposition process has been preformed. These results were confirmed for cases of nitride films having thicknesses of 30, 36, 38 Å, respectively. The reason why there is no tearing of the nitride film (199) is because most oxygen ions existing in a discharge region between the guide ring (5) and the semiconductor substrate (196) are absorbed into the semiconductor substrate (196) via the relatively thin nitride film (199) without reacting with the nitride film (199).

As described above, the present invention prevents the nitride film serving as a trench liner from being torn at the beveled part of a semiconductor substrate during an HDP oxide film deposition process. More specifically, the present invention provides a guide ring of an HDP oxide film apparatus, a technique of applying RF power in an HDP oxide film apparatus, and provides a method of forming a thin nitride film in respective ways that mitigate the attack of the nitride liner by oxygen ions of plasma during the HDP oxide film deposition process.

Finally, although the present invention has been described above with reference to the preferred embodiments thereof, various changes in form and details may be made thereto without departing from the true spirit and scope of the invention as defined by the appended claims.

1. A high density plasma oxide film deposition apparatus comprising:
a chuck having an upper surface onto which a semiconductor substrate is to be loaded, and an outer peripheral side wall;
an upper electrode confronting and spaced from the upper surface of said chuck; and
a guide ring extending around said chuck, said guide ring comprising a first annular portion having an inner peripheral side wall surrounding the outer peripheral side wall of said chuck, a second annular portion extending upwardly from a n outer peripheral region of said first annular portion and having an inner peripheral side wall disposed radially outwardly of the inner peripheral side wall of said first annular portion, and at least three protrusions extending from the inner peripheral side wall of said second annular portion toward the inner peripheral side wall of said first annular portion, said protrusions being spaced from one another in the circumferential direction of said second annular portion, and said protrusions having terminal ends remote from the inner peripheral side wall of said second annular portion and situated radially outwardly of the inner peripheral side wall of said first annular portion, said terminal ends lying along a circle whose diameter is greater than the inner diameter of said first annular portion.

2. The high density plasma oxide film deposition apparatus of claim 1, wherein said chuck is an electrostatic chuck.

3. The high density plasma oxide film deposition apparatus of claim 2, wherein the apparatus further comprises a first power source connected to said upper electrode, and a second power source connected to said electrostatic chuck.

4. The high density plasma oxide film deposition apparatus of claim 3, wherein said first power source has a bias and a radio frequency within ranges of 2000˜3000 Watts and 1.8˜2.2 MHz, respectively, and said second power source has a bias and a radio frequency within ranges of 2000˜3000 Watts and 13.37˜13.64 MHz, respectively.

5. The high density plasma oxide film deposition apparatus of claim 3, wherein said first power source has a bias and a radio frequency within ranges of 2000˜3000 Watts and 13.37˜13.64 MHz, respectively, and said second power source has a bias and a radio frequency within ranges of 2000˜3000 Watts and 1.8˜0.2 MHz, respectively.

6. The high density plasma oxide film deposition apparatus of claim 1, wherein the apparatus further comprises a chamber within which the chuck, the upper electrode and the guide ring are disposed.

7. The high density plasma oxide film deposition apparatus of claim 1, wherein the first and the second annular portions of said guide ring are concentric.

8. The high density plasma oxide film deposition apparatus of claim 7, wherein said protrusions are spaced equidistantly from each other in the circumferential direction of said second annular portion.

9. A high density plasma oxide film deposition apparatus comprising:
a chuck having an upper surface onto which a semiconductor substrate is to be loaded, and an outer peripheral side wall;
an upper electrode confronting and spaced from the upper surface of said chuck; and
a guide ring extending around said chuck, said guide ring comprising a first annular portion having an inner peripheral side wall surrounding the outer peripheral side wall of said chuck, a second annular portion extending upwardly from an outer peripheral region of said first annular portion and having an inner peripheral side wall disposed radially outwardly of the inner peripheral side wall of said first annular portion, and a third annular portion protruding upwardly from an upper surface of said second annular portion, said third annular portion having an inclined inner peripheral side wall extending contiguously from the inner peripheral side wall of said second annular portion such that the inside diameter of said third annular portion at the top of said inclined wall is greater than the inside diameter of the third annular portion at the bottom of said inclined wall, and said third annular portion having openings therethrough and through which respective parts of an upper surface of the second annular portion are exposed.

10. The high density plasma oxide film deposition apparatus of claim 9, wherein said chuck is an electrostatic chuck.

11. The high density plasma oxide film deposition apparatus of claim 9, wherein the apparatus further comprises a first power source connected to said upper electrode, and a second power source connected to said electrostatic chuck.

12. The high density plasma oxide film deposition apparatus of claim 11, wherein said first power source has a bias and a radio frequency within ranges of 2000˜3000 Watts and 1.8˜2.2 MHz, respectively, and said second power source has a bias and a radio frequency within ranges of 2000˜3000 Watts and 13.37˜13.64 MHz, respectively.

13. The high density plasma oxide film deposition apparatus of claim 11, wherein said first power source has a bias and a radio frequency within ranges of 2000˜3000 Watts and 13.37˜13.64 MHz, respectively, and said second power source has a bias and a radio frequency within ranges of 2000˜3000 Watts and 1.8˜2.2 MHz, respectively.

14. The high density plasma oxide film deposition apparatus of claim 9, wherein the apparatus further comprises a chamber within which the chuck, the upper electrode and the guide ring are disposed.

15. A method of manufacturing a semiconductor device, including the use of a high density plasma oxide film deposition apparatus having a process chamber, a chuck disposed in the process chamber, an upper electrode disposed in the process chamber as spaced from an upper surface of the chuck, and a guide ring surrounding the chuck in the process chamber, said method comprising:
processing a semiconductor substrate having a beveled part at an outer peripheral edge thereof, said processing comprising forming a nitride film on the substrate as a liner;
injecting process gases, including oxygen, into the chamber; and
while the processed semiconductor substrate is disposed on the chuck and the process gases are in the chamber
applying a first power having a bias and a radio frequency within ranges of 2000˜3000 Watts and 13.37˜13.64 MHz, respectively, to the upper electrode to convert the process gases injected into the process chamber into plasma, and
applying a second power having a bias and a radio frequency within ranges of 2000˜3000 Watts and 1.8˜2.2 MHz, respectively, to a lower electrode situated beneath the semiconductor substrate to attract ions of the plasma onto the semiconductor substrate.

16. The method of claim 15, wherein said processing the semiconductor substrate comprises sequentially forming a pad oxide film and an active nitride film on the semiconductor substrate such that the active nitride film divides an active region from an inactive region of the substrate, sequentially etching the pad oxide film and the semiconductor substrate in the inactive region using the active nitride film as a mask to thereby form a trench in the substrate, forming an insulating film on the active nitride film and in the trench, removing the active nitride film from the beveled part of the semiconductor substrate and from the lower surface of the semiconductor substrate using the insulating film as a mask, and wherein the nitride film serving as a liner for the semiconductor substrate is formed on the insulating film.

17. A method of manufacturing a semiconductor device, including the use of a high density plasma oxide film deposition apparatus having a process chamber, a chuck disposed in the process chamber, an upper electrode disposed in the process chamber as spaced from an upper surface of the chuck, and a guide ring surrounding the chuck in the process chamber, said method comprising:
processing a semiconductor substrate having a beveled part at an outer peripheral edge thereof, said processing comprising
(a) sequentially forming a pad oxide film and an active nitride film on the semiconductor substrate such that the active nitride film divides an active region from an inactive region of the substrate,
(b) sequentially etching the pad oxide film and the semiconductor substrate in the inactive region using the active nitride film as a mask to thereby form a trench in the substrate,
(c) forming an insulating film on the active nitride film and in the trench,
(d) removing the active nitride film from the beveled part of the semiconductor substrate and from the lower surface of the semiconductor substrate using the insulating film as a mask, and
(e) forming a nitride film serving as a liner for the semiconductor substrate on the insulating film to a thickness of 25˜40 Å;
injecting process gases, including oxygen, into the chamber; and
while the processed semiconductor substrate is disposed on the chuck and the process gases are in the chamber
applying a first power to the upper electrode to convert the process gases injected into the process chamber into plasma, and
applying a second power to a lower electrode situated beneath the semiconductor substrate to attract ions of the plasma onto the semiconductor substrate.

18. The method of claim 17, wherein the first power has a bias and a radio frequency within ranges of 2000˜3000 Watts and 1.8˜2.2 MHz, respectively, and the second power has a bias and a radio frequency within ranges of 2000˜3000 Watts and 13.37˜13.64 MHz, respectively.

19. The method of claim 17, wherein the first power has a bias and a radio frequency within ranges of 2000˜3000 Watts and 13.37˜13.64 MHz, respectively, and the second power has a bias and the radio frequency within ranges of 2000˜3000 Watts and 1.8˜2.2 MHz, respectively.
